(19) United States
(12) Patent Application Publication
(10) Pub. No.: US 2025/0316473 A1
(43) Pub. Date: Oct. 9, 2025

(54) METHOD OF DEPOSITING THIN LAYER

(71) Applicant: SAMSUNG ELECTRONICS CO., LTD., SUWON-SI (KR)

(72) Inventors: Youngsang CHO, Suwon-si, Gyeonggi-do (KR); Sung Gap IM, Daejeon (KR); Sanghoon AHN, Suwon-si, Gyeonggi-do (KR); Taehyun NAM, Daejeon (KR); Chungryeol LEE, Daejeon (KR); Sukwon JANG, Daejeon (KR)

(73) Assignee: Korea Advanced Institute of Science and Technology, Daejeon (KR)

(21) Appl. No.: 18/921,365

(22) Filed: Oct. 21, 2024

(30) Foreign Application Priority Data
Apr. 4, 2024 (KR) 10-2024-0046067

(51) Int. Cl. H01L 21/02

(52) U.S. Cl. CPC H01L 21/02118; H01L 21/02216; H01L 21/02274; H01L 21/02315

(57) ABSTRACT

A method of depositing a thin layer includes forming a substrate including first and second portions. A thin layer is formed only on the first portion. The second portion includes a material having a plurality of oxidation states. The forming of the thin layer includes supplying an initiator and a monomer on the first and second portions. The initiator includes a material forming radicals by application of a decomposition energy inducing one of a thermal decomposition process, a photodecomposition process, and an oxidation-reduction reaction process. A deposition process is performed reacting the initiator and the monomer with each other. The performing of the deposition process includes applying the decomposition energy to form the radicals from the initiator. The monomer includes at least one multiple bond between carbon atoms. A polymer is formed by an initiation reaction between the radical and the monomer. The thin layer includes the polymer.

### CROSS-REFERENCE TO RELATED APPLICATIONS

This application claims priority under 35 U.S.C. § 119 to Korean Patent Application No. 10-2024-0046067, filed on Apr. 4, 2024 in the Korean Intellectual Property Office, the disclosure of which is incorporated by reference in its entirety herein.

### 1. TECHNICAL FIELD

Embodiments of the present inventive concept relate to a method of depositing a thin layer. More particularly, embodiments of the present inventive concept relate to a method of depositing a thin layer using an initiated chemical vapor deposition (iCVD) process.

### 2. DISCUSSION OF RELATED ART

The usage of semiconductor devices in the electronic industry has increased due to the small-size, multifunctionality and low-cost characteristics of semiconductor devices. Generally, semiconductor devices are classified into a memory device for storing data, a logic device for processing data, and a hybrid device for performing various functions.

The demand for higher device integration has increased along with the advancement of the electronics industry. A higher device integration may cause several problems, such as reduced process margins in exposure processes for patterning fine patterns. As such, it may become more difficult to fabricate integrated circuit devices. Accordingly, research is being conducted to satisfy the demand for high integration and high speed operation of semiconductor devices.

### SUMMARY

An object of the inventive concept is to provide a method of depositing a thin layer that increases reliability of a manufacturing process.

An object of the inventive concept is to provide a method of depositing a thin layer with an easy manufacturing process and reduced costs.

According to an embodiment of the present inventive concept, a method of depositing a thin layer includes forming a substrate including first and second portions. A thin layer is formed only on the first portion. The second portion includes a material having a plurality of oxidation states. The forming of the thin layer includes supplying an initiator and a monomer on the first and second portions. The initiator includes a material forming radicals by application of a decomposition energy inducing one of a thermal decomposition process, a photodecomposition process, and an oxidation-reduction reaction process. A deposition process is performed reacting the initiator and the monomer with each other. The performing of the deposition process includes applying the decomposition energy to form the radicals from the initiator. The monomer includes at least one multiple bond between carbon atoms. A polymer is formed by an initiation reaction between the radical and the monomer. The thin layer includes the polymer.

According to an embodiment of the present inventive concept, a method of depositing a thin layer includes forming a substrate including a first portion, a second portion, and a third portion. A thin layer is formed only on the first portion and the third portion. The second portion and the third portion include a material having a plurality of oxidation states. The forming of the thin layer includes supplying electrons only to the third portion. An initiator and a monomer are supplied on the first portion, the second portion and the third portion. The initiator includes a material forming radicals by application of a decomposition energy inducing one of a thermal decomposition process, a photodecomposition process, and an oxidation-reduction reaction process. A deposition process is performed reacting the initiator and the monomer with each other. The performing of the deposition process includes applying the decomposition energy to form the radicals from the initiator. The monomer includes at least one multiple bond between carbon atoms. A polymer is formed by an initiation reaction between the radicals formed from the initiator and the monomer. The thin layer includes the polymer.

### BRIEF DESCRIPTION OF THE DRAWINGS

Non-limiting embodiments of the present inventive concept will be more clearly understood from the following brief description taken in conjunction with the accompanying drawings. The accompanying drawings represent non-limiting embodiments of the present inventive concept as described herein.

FIGS. 1 to 4 are diagrams showing a method of depositing a thin layer according to embodiments of the present inventive concept.

FIGS. 5 to 9 are diagrams showing a method of depositing a thin layer according to some embodiments of the present inventive concept.

### DETAILED DESCRIPTION OF EMBODIMENTS

Hereinafter, the present inventive concept will be described in detail by explaining non-limiting embodiments of the present inventive concept with reference to the accompanying drawings.

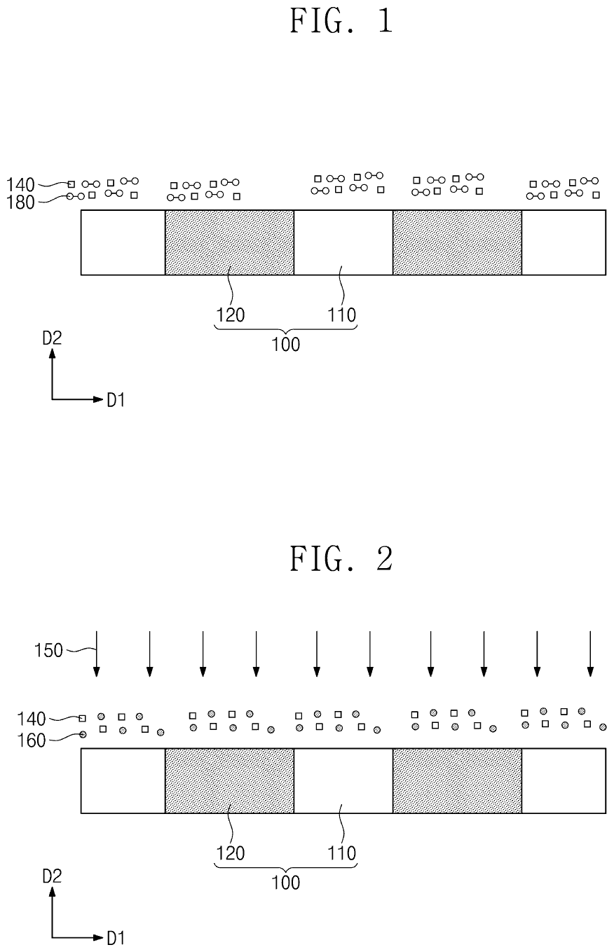

FIGS. 1 to 4 are diagrams showing a method of depositing a thin layer according to embodiments of the present inventive concept.

Referring to FIG. 1, a substrate 100 may be provided. In an embodiment, the substrate 100 may include a first portion 110 and a second portion 120 that are separated from each other in a first direction D1. A plurality of first portions 110 and a plurality of second portions 120 may be provided. In an embodiment, the first direction D1 may be a direction parallel to an upper surface of the substrate 100. Thus, in an embodiment the substrate 100 may include a plurality of first portions 110 and a plurality of second portions 120 alternately arranged along the first direction D1.

The first portion 110 and the second portion 120 may include different materials from each other. For example, in an embodiment the first portion 110 may include one compound selected from silicon, silicon nitride, and silicon oxide. The second portion 120 may include a material that acts as a radical scavenger and may include a material that has multiple oxidation states. The material having “multiple oxidation states” or “a plurality of oxidation states” may mean a material capable of forming a stable compound even when it receives electrons from a radical. In an embodiment, the second portion 120 may include, for example, a transition metal or a transition metal oxide, and may include, for example, one or more compounds selected from Sc, Ti, Cr, Mn, Fe, Co, Ni, Cu, Zr, Nb, Mo, Tc, Ru, Rh, Rd, Ag, Hf, Ta, W, Re, Os, Ir, Pt, Au, Hg, and an oxide thereof.

An initiator 180 and a monomer 140 may be provided to the first portion 110 and the second portion 120. For example, in an embodiment the initiator 180 and the monomer 140 may be evenly distributed on an upper surface of the first portion 110 and an upper surface of the second portion 120. A deposition process for forming a thin layer 200 may be performed by reacting the initiator 180 and the monomer 140 with each other as described below.

In an embodiment, the initiator 180 may form a radical through a thermal decomposition process, a plasma decomposition process and/or an oxidation-reduction reaction process. In an embodiment, the initiator 180 may include a compound of the following Formula 1 and, for example, may form an oxygen radical.

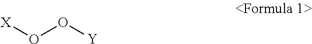

In Formula 1, each of X and Y may independently be an alkyl group having 1 to 5 carbon atoms, an alkynyl group having 2 to 15 carbon atoms, a substituted carbonyl group or an unsubstituted carbonyl group. For example, in an embodiment, the initiator may include at least one compound selected from tert-butyl peroxide (TBPO), tert-amylperoxide, tert-butylperoxybenzoate, and perfluorooctanesulfonyl fluoride.

In an embodiment, the monomer 140 may include at least one multiple bond. For example, the monomer 140 may include a double bond or triple bond between carbons. The monomer 140 may include a material capable of polymerizing a polymer by breaking the multiple bonds from the radical formed from the initiator 180. In an embodiment, the monomer 140 may include a compound of Formula 2 below.

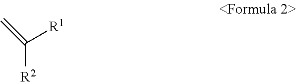

Each of R¹ and R² may be independently hydrogen, an alkyl group with 1 to 15 carbon atoms, an alkynyl group with 1 to 15 carbon atoms, an aryl group with 1 to 15 carbon atoms, a substituted carboxyl group, an unsubstituted carboxyl group, a substituted carbonyl group, an unsubstituted carbonyl group, a substituted alkoxy group or an unsubstituted alkoxy group.

For example, in an embodiment, the monomer may include at least one compound selected from 1,3,5-trimethyl-1,3,5-trivinylcyclotrisiloxane (V3D3), divinylbenzene (DVB), cyclohexyl methacrylate, glycidyl methacrylate, hydroxyethyl methacrylate, methacrylic anhydride, ethylene glycol dimethacrylate, 1,3-butanediol diacrylate, 1,3,5,7-tetravinyl-1,3,5,7-tetramethyl cyclotetrasiloxane, vinylimidazole, acrylic acid, N-vinyl-2-pyrrolidone and 1H,1H,2H,2H-perfluorodecyl methacrylate.

Referring to FIG. 2, a decomposition energy 150 may be provided to the initiator 180 to form a radical 160. In an embodiment, the decomposition energy 150 may be, for example, heat energy, plasma, and oxidizing agent. In an embodiment, the forming of the radical 160 from the initiator 180 may be performed at a temperature in a range of about 30° C. to about 250° C. The forming of the radical 160 may be performed at a low temperature, and thus the substrate 100 may not be damaged, thereby increasing reliability of the manufacturing process.

In an embodiment, the radical 160 forming from the initiator 180 may be as shown in Scheme 1 below.

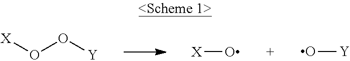

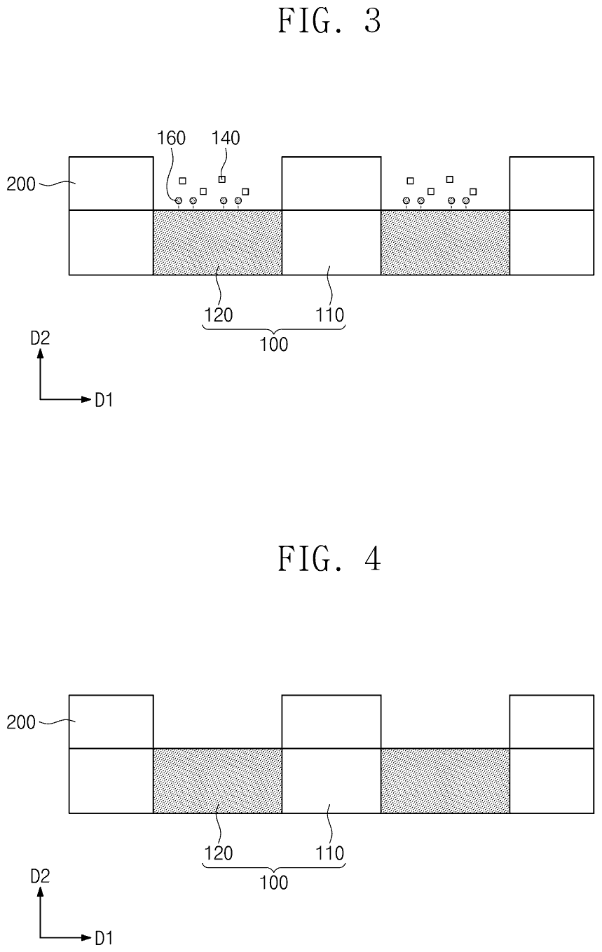

Referring to FIG. 3, a thin layer 200 may be formed on the first portion 110 (e.g., formed directly thereon in the second direction D2). In an embodiment, the forming of the thin layer 200 may be initiated from a reaction between the radical 160 formed from the initiator 180 and the multiple bonds of the monomer 140. The reaction between the radical 160 and the multiple bonds of the monomer 140 may be as shown in Scheme 2 below, and Scheme 2 may be an initiation step which forms a radical of the monomer 140.

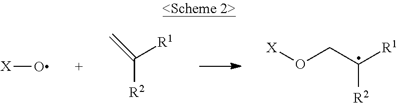

Referring to Scheme 3 below, the radical of the monomer 140 may react with the multiple bond of another monomer. Scheme 3 may be a propagation step, and the radical reaction may occur in chain. Due to the chain radical reaction, monomers may form a polymer, and a chain length of the monomers may increase.

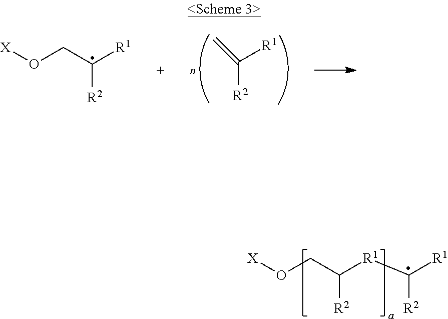

Referring to Scheme 4 below, the chain reaction of radicals may be terminated. In an embodiment, radicals of two growing monomer chains may be combined to terminate the radical reaction, or a foreign substance may terminate the radical reaction.

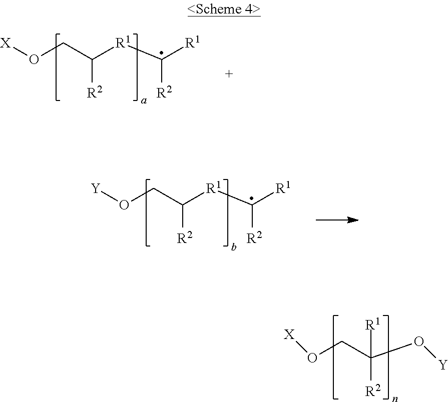

n may be the sum of a and b, and n may be 2 to 100,000. Scheme 4 may be a termination step.

A thin layer 200 may include a polymer formed through the chain radical reaction. In an embodiment, the polymer may include a compound of Formula 3 below.

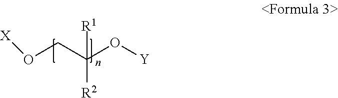

Referring again to FIG. 3, the thin layer 200 may not be formed on the second portion 120. Among the radicals 160 formed from the initiator 180, the radical 160 adjacent to the second portion 120 may not participate in the initiation reaction by interacting (e.g., bonding) with the material having the plurality of oxidation states of the second portion 120. For example, in an embodiment in which the second portion 120 includes a transition metal, the radical 160 may provide electrons to d-orbitals of the transition metal. Electrons provided from the radical 160 may be stabilized by interacting with electrons in the d-orbitals of the transition metal, which prevents the initiation reaction according to Scheme 2 from occurring.

According to an embodiment of the present inventive concept, the second portion 120 may act as a radical scavenger, and a thin layer may not be formed on the second portion 120. For example, a thin layer may be selectively deposited on a desired surface (e.g., on the first portion 110) without a radical inhibitor or a mask pattern. Accordingly, a manufacturing process may be simplified, and cost of the manufacturing process may be reduced.

In an embodiment, when forming the thin layer 200, a partial pressure of the monomer 140 with respect to a saturation pressure of the monomer 140 may be in a range of about 0.01 to about 0.2. The saturation pressure may be a saturation pressure of the monomer 140 at a temperature of the substrate 100. When the partial pressure of the monomer 140 exceeds 0.2, the thin layer 200 may not be formed conformally on the first portion 110, and a thickness dispersion of the thin layer 200 may increase.

Referring to FIG. 4, the radical 160 and the monomer 140 on the second portion 120 may be removed. For example, in an embodiment the removing of the radical 160 and the monomer 140 may include injecting an inert gas for the removal thereof. For example, in an embodiment the inert gas may be any one of argon and nitrogen.

The manufacturing process collectively shown in FIGS. 1 to 4 may be defined as one super cycle. In an embodiment, one super cycle may proceed for a time period in a range of about 10 minutes to about 30 minutes. When progress time of the one super cycle is less than about 10 minutes, the thin layer 200 may not be formed on the first portion 110, and when the progress time of the one super cycle exceeds about 30 minutes, the thin layer 200 may be formed on the second portion 120. For example, for selective thin layer deposition, the time period to perform one super cycle may be in a range of about 10 minutes to about 30 minutes. To increase the thickness of the thin layer 200, the super cycle may be performed several times. In an embodiment, the forming of the thin layer 200 may be, for example, initiated chemical vapor deposition (iCVD).

### Experiment Example

In a method of depositing a thin layer according to an embodiment of the present inventive concept, tert-butyl peroxide (TBPO) was used as an initiator. Divinylbenzene (DVB) was used as a monomer. Using an initiator and a monomer, polydivinylbenzene (pDVB) was formed according to Scheme 6 below.

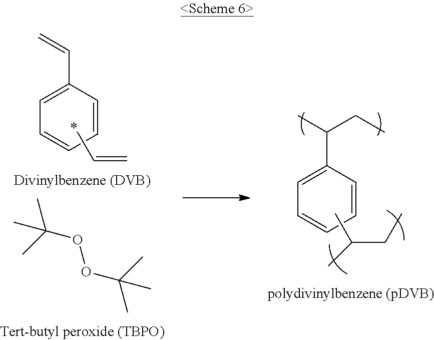

The initiator and monomer were reacted in a gas phase to deposit a polymer on a substrate.

### Example 1

Example 1 used Si as a substrate, and a deposition process was carried out for 10 minutes. A DVB flow rate was set to 3 sccm, and a TBPO flow rate was set to 1 sccm. A process pressure was adjusted to 200 mTorr. A temperature of the substrate was set to 50° C. A temperature of a filament was set to 130° C., and Pm/Psat was set to 0.153.

### Example 2

Example 2 used SiCO as a substrate, and a deposition process was carried out for 10 minutes. A DVB flow rate was set to 3 sccm, and a TBPO flow rate was set to 1 sccm. A process pressure was adjusted to 200 mTorr. A temperature of the substrate was set to 50° C. A temperature of a filament was set to 130° C., and Pm/Psat was set to 0.153.

### Example 3

Example 3 used SiCN as a substrate, and a deposition process was carried out for 10 minutes. A DVB flow rate was set to 2 sccm, and a TBPO flow rate was set to 1 sccm. A process pressure was adjusted to 200 mTorr. A temperature of the substrate was set to 70° C. A temperature of a filament was set to 130° C., and Pm/Psat was set to 0.153.

### Example 4

Example 4 used SiO₂ as a substrate, and a deposition process was carried out for 10 minutes. A DVB flow rate was set to 2 sccm, and a TBPO flow rate was set to 1 sccm. A process pressure was adjusted to 200 mTorr. A temperature of the substrate was set to 50° C. A temperature of a filament was set to 130° C., and Pm/Psat was set to 0.153.

### Comparative Example 1

Comparative Example 1 used WO₃ as a substrate, and a deposition process was carried out for 35 minutes. A DVB flow rate was set to 2 sccm, and a TBPO flow rate was set to 1 sccm. A process pressure was adjusted to 200 mTorr. A temperature of the substrate was set to 50° C. A temperature of a filament was set to 130° C., and Pm/Psat was set to 0.153.

Results showing thin layer deposition thicknesses on a substrate of Examples 1 to 4 and Comparative Example 1 are shown in Table 1 below.

TABLE 1

| | Example | Example | Example | Example | Comparative |
|---|---|---|---|---|---|
| | 1 | 2 | 3 | 4 | Example 1 |
| Thickness | 4.92 nm | 3.23 nm | 3.08 nm | 0 nm | 2.86 nm |
| of thin | | | | | |
| layer | | | | | |

As shown in Table 1 above, in Examples 1 to 3, it is shown that when the thin layer deposition process was performed for 10 minutes, the thin layer was deposited on the substrate. In Example 4, it was confirmed that the thin layer was not deposited on a substrate including the transition metal. Accordingly, it was confirmed that the thin layer may be selectively deposited on the first portion not including the transition metal, and may not be deposited on the second portion including the transition metal. In Comparative Example 1, it is shown that even when the substrate including the transition metal, the thin layer was deposited when the thin layer deposition process exceeds 30 minutes. Therefore, it is confirmed that for selective thin layer deposition, the thin layer deposition process may be performed for 10 to 30 minutes.

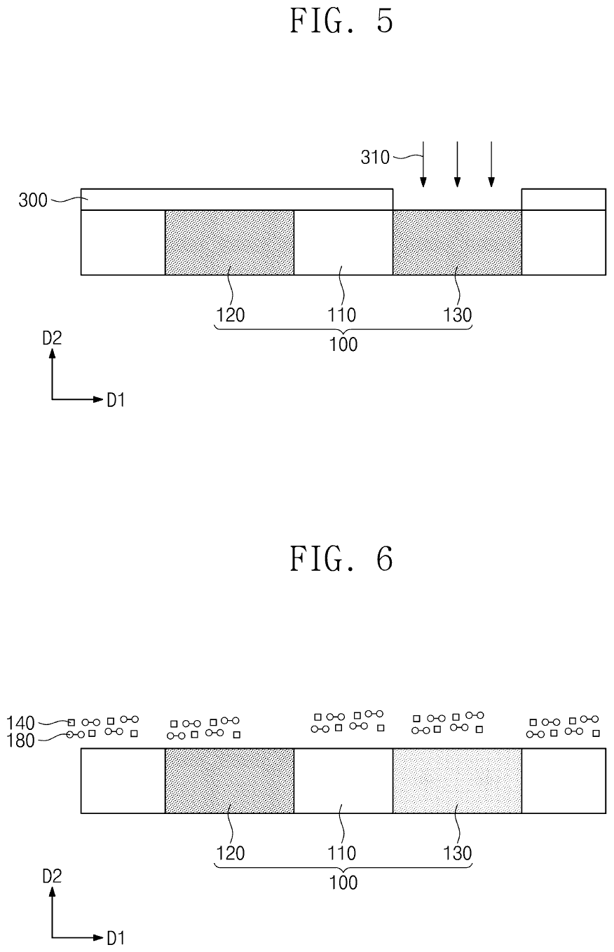

FIGS. 5 to 9 are diagrams showing a method of depositing a thin layer according to some embodiments of the present inventive concept. For simplicity of explanation, descriptions that overlap with the thin layer deposition manufacturing process described with reference to FIGS. 1 to 4 may be omitted.

Referring to FIG. 5, in an embodiment a substrate 100 may include a first portion 110, a second portion 120, and a third portion 130 arranged in the first direction D1. In an embodiment, the first portion 110 and the second portion 120 may include different materials from each other, and the second portion 120 and the third portion 130 may include the same material as each other. For example, in an embodiment the first portion 110 may include one compound selected from silicon, silicon nitride, and silicon oxide. The second portion 120 and the third portion 130 may include a material that acts as a radical scavenger and may include a material having multiple oxidation states (e.g., a plurality of oxidation states). The “material having multiple oxidation states” or “having a plurality of oxidation states” may mean a material capable of forming a stable compound even when it receives electrons from a radical. In an embodiment, the second portion 120 and the third portion 130 may include, for example, a transition metal or a transition metal oxide, and may include one or more of, for example, Sc, Ti, Cr, Mn, Fe, Co, Ni, Cu, Zr, Nb, Mo, Tc, Ru, Rh, Rd, Ag, Hf, Ta, W, Re, Os, Ir, Pt, Au, Hg, and an oxide thereof. The first portion 110, the second portion 120, and the third portion 130 may be spaced apart from each other in a first direction D1 and may be arranged alternately in the first direction D1. In an embodiment, the first direction D1 may be a direction parallel to an upper surface of the substrate 100.

Electrons 310 may be supplied to the third portion 130. For example, in an embodiment the supplying of the electrons 310 may include forming a mask pattern 300 on the first portion 110 and the second portion 120, and supplying the electrons to the third portion 130. In an embodiment, the supplying of the electrons 310 may be, for example, by plasma processing. However, embodiments of the present inventive concept are not necessarily limited thereto. By supplying the electrons 310, the material having the plurality of oxidation states in the third portion 130 may be reduced. For example, in an embodiment in which the third portion 130 includes a transition metal, all d-orbitals of the third portion 130 may be filled.

Referring to FIG. 6, an initiator 180 and a monomer 140 may be supplied to the first portion 110, the second portion 120, and the third portion 130. In an embodiment, the initiator 180 and the monomer 140 may be evenly distributed on the first portion 110, the second portion 120, and the third portion 130, such as on upper surfaces of the first portion 110, the second portion 120, and the third portion 130.

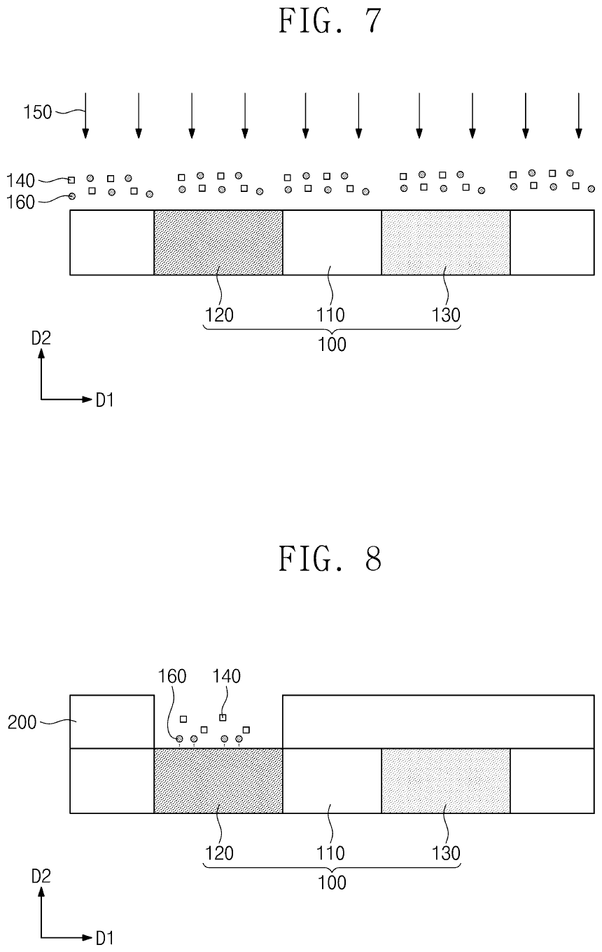

Referring to FIG. 7, the initiator 180 may form radicals 160 through decomposition energy 150. In an embodiment, the decomposition energy 150 may be thermal energy, plasma, or oxidizing agent.

Referring to FIG. 8, a thin layer 200 may be formed on the first portion 110 and the third portion 130. In the case of the third portion 130, it may no longer receive the electrons, and thus the radical 160 decomposed from the initiator 180 may not react (e.g., bind) with the third portion 130. For example, in an embodiment in which the third portion 130 includes the transition metal, the d-orbitals of the third portion 130 may be filled with the electrons due to the plasma treatment. Therefore, the radical on the third portion 130 may not be able to provide electrons to the third portion 130, and the radical may not be stabilized. Accordingly, the radical 160 may cause a chain polymerization reaction with the monomer to form a polymer on the third portion 130.

The thin layer 200 may not be formed on the second portion 120. The radical 160 on the second portion 120 may not participate in the initiation reaction by interacting (e.g., binding) with the material having the plurality of oxidation states of the second portion 120. For example, in an embodiment in which the material having multiple oxidation states is the transition metal, the radical 160 may provide the electrons to the d-orbitals of the transition metal. The electrons provided from the radical 160 may be stabilized by interacting with electrons in the d-orbitals of the transition metal, and as a result, the initiation reaction may not proceed. Therefore, the thin layer may not be formed on the second portion 120.

According to an embodiment of the present inventive concept, the thin layer may be deposited on a desired surface (e.g., on the third portion 130) by controlling the oxidation state of the substrate. For example, the thin layer may be selectively deposited on the desired portion without a separate radical inhibitor or a separate mask pattern. Therefore, the manufacturing process may be simplified and cost of the manufacturing process may be reduced.

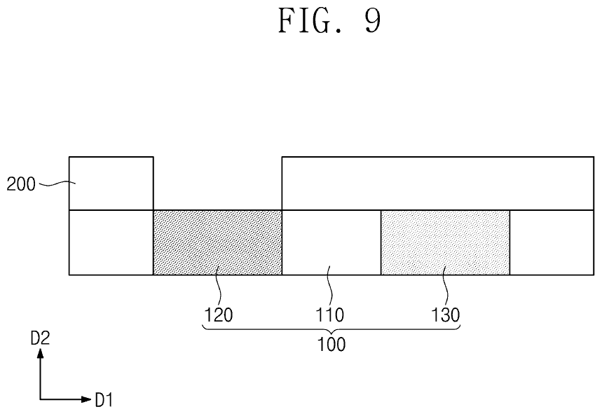

Referring to FIG. 9, the radical 160 and the monomer 140 on the second portion 120 may be removed. For example, in an embodiment the removing of the radical 160 and the monomer 140 may include removing the radical 160 and the monomer 140 by injecting an inert gas. For example, in an embodiment the inert gas may be any one of argon and nitrogen.

The manufacturing process collectively shown in FIGS. 6 to 9 may be defined as one super cycle. In an embodiment, a time period for the performance of one super cycle may be in a range of about 10 minutes to about 30 minutes. When the progress time of the one super cycle is less than about 10 minutes, the thin layer 200 may not be formed on the first portion, and when the progress time of the one super cycle exceeds about 30 minutes, the thin layer 200 may be formed on the portion 120. For example, for selective thin layer deposition, the progress time of one super cycle may be in a range of about 10 to about 30 minutes. The super cycle may be performed several times to deposit the thin layer 200 to a desired thickness. In an embodiment, the forming of the thin layer 200 may be, for example, initiated chemical vapor deposition (iCVD).

According to an embodiment of the present inventive concept, the thin layer may be deposited on the substrate including the first portion and the second portion. The second portion may include the material that acts as the radical scavenger, for example, a material having multiple oxidation states. Depositing the thin layer may be performed at the low temperature without damaging the substrate, thereby increasing the reliability of the manufacturing process.

Additionally, the thin layer deposited by the initiated chemical vapor deposition (iCVD) method may not be formed in the second portion, and may be selectively deposited in the first portion. Therefore, the thin layer may be selectively deposited on the desired portion without the radical inhibitor, the mask pattern, etc. Accordingly, the manufacturing process may be simplified, and the cost of the manufacturing process may be reduced.

While embodiments of the present inventive concept are described above, a person skilled in the art may understand that many modifications and variations may be made without departing from the spirit and scope of the present inventive concept. Accordingly, the described embodiments of the present inventive concept should be considered in all respects as illustrative and not restrictive.

What is claimed is:

1. A method of depositing a thin layer, the method comprising:
forming a substrate including a first portion and a second portion; and
forming a thin layer on the first portion,
wherein the second portion includes a material having a plurality of oxidation states,
wherein the forming of the thin layer includes:
supplying an initiator and a monomer on the first portion and the second portion, wherein the initiator includes a material forming radicals by application of a decomposition energy inducing one of a thermal decomposition process, a photodecomposition process, and an oxidation-reduction reaction process; and
performing a deposition process reacting the initiator and the monomer with each other, the performing of the deposition process includes applying the decomposition energy to form the radicals from the initiator,
wherein the monomer includes at least one multiple bond between carbon atoms,
wherein a polymer is formed by an initiation reaction between the radicals formed from the initiator and the monomer, and
wherein the thin layer includes the polymer.

2. The method of claim 1, wherein the first portion and the second portion include different materials from each other.

3. The method of claim 1, wherein the material having the plurality of oxidation states of the second portion includes a transition metal or a transition metal oxide.

4. The method of claim 1, wherein the forming of the thin layer is performed for a time period in a range of about 10 to about 30 minutes.

5. The method of claim 1, wherein the initiator includes a compound represented by Formula 1: 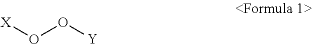
wherein each of X and Y is independently an alkyl group having 1 to 5 carbon atoms, an alkynyl group having 2 to 15 carbon atoms, a substituted carbonyl group or an unsubstituted carbonyl group.

6. The method of claim 5, wherein the monomer includes a compound represented by Formula 2: 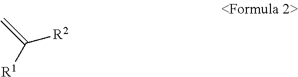
wherein each of R¹ and R² is independently hydrogen, an alkyl group having 1 to 15 carbon atoms, an alkynyl group having 1 to 15 carbon atoms, an aryl group having 1 to 15 carbon atoms, a substituted carboxyl group, an unsubstituted carboxyl group, a substituted carbonyl group, an unsubstituted carbonyl group, a substituted alkoxyl group or an unsubstituted alkoxyl group.

7. The method of claim 6, wherein the polymer includes a compound represented by Formula 3: 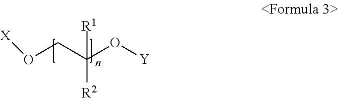
wherein each of R¹ and R² is independently hydrogen, an alkyl group having 1 to 15 carbon atoms, an alkynyl group having 1 to 15 carbon atoms, an aryl group having 1 to 15 carbon atoms, a substituted carboxyl group, an unsubstituted carboxyl group, a substituted carbonyl group, an unsubstituted carbonyl group, a substituted alkoxyl group or an unsubstituted alkoxyl group,
wherein each of X and Y is independently an alkyl group having 1 to 5 carbon atoms, an alkynyl group having 2 to 15 carbon atoms, a substituted carbonyl group or an unsubstituted carbonyl group, and
wherein n is from 2 to 100,000.

8. The method of claim 1, wherein the initiator includes at least one compound selected from tert-butyl peroxide (TBPO), tert-amylperoxide, tert-butylperoxybenzoate, and perfluorooctanesulfonyl fluoride.

9. The method of claim 1, wherein the monomer includes at least one compound selected from 1,3,5-trimethyl-1,3,5-trivinylcyclotrisiloxane, divinylbenzene (DVB), cyclohexyl methacrylate, glycidyl methacrylate, hydroxyethyl methacrylate, methacrylic anhydride, ethylene glycol dimethacrylate, 1,3-butanediol diacrylate, 1,3,5,7-tetravinyl-1,3,5,7-tetramethyl cyclotetrasiloxane, vinylimidazole, acrylic acid, N-vinyl-2-pyrrolidone, and 1H,1H,2H,2H-perfluorodecyl methacrylate.

10. The method of claim 1, wherein the first portion includes one compound selected from silicon, silicon nitride, and silicon oxide.

11. The method of claim 3, wherein the material having the plurality of oxidation states of the second portion includes one or more compounds selected from Sc, Ti, Cr, Mn, Fe, Co, Ni, Cu, Zr, Nb, Mo, Tc, Ru, Rh, Rd, Ag, Hf, Ta, W, Re, Os, Ir, Pt, Au, Hg, and mixtures thereof.

12. The method of claim 1, wherein the thin layer is formed at a temperature in a range of about 30° C. to about 250° C.

13. The method of claim 1, wherein a partial pressure of the monomer with respect to a saturation pressure of the monomer is in a range of about 0.01 to about 0.2.

14. The method of claim 1, wherein the forming of the thin layer includes a initiated chemical vapor deposition process (iCVD) using an initiator.

15. A method of depositing a thin layer, the method comprising:
forming a substrate including a first portion, a second portion, and a third portion; and
forming a thin layer on the first portion and the third portion,
wherein the second portion and the third portion include a material having a plurality of oxidation states,
wherein the forming of the thin layer includes:
supplying electrons to the third portion;
supplying an initiator and a monomer on the first portion, the second portion and the third portion, wherein the initiator includes a material forming radicals by application of a decomposition energy inducing one of a thermal decomposition process, a photodecomposition process, and an oxidation-reduction reaction process; and
performing a deposition process reacting the initiator and the monomer with each other, the performing of the deposition process includes applying the decomposition energy to form the radicals from the initiator;
wherein the monomer includes at least one multiple bond between carbon atoms,
wherein a polymer is formed by an initiation reaction between the radicals formed from the initiator and the monomer, and
wherein the thin layer includes the polymer.

16. The method of claim 15, wherein the supplying of the electrons to the third portion includes performing a plasma treatment process.

17. The method of claim 15, wherein the second portion and the third portion include a same material as each other.

18. The method of claim 15, wherein the material having the plurality of oxidation states of the second portion and the third portion include a transition metal or a transition metal oxide.

19. The method of claim 15, wherein the thin layer is formed at a temperature in a range of about 30° C. to about 250° C.

20. The method of claim 18, wherein the material having the plurality of oxidation states of each of the second portion and the third portion includes one or more of Sc, Ti, Cr, Mn, Fe, Co, Ni, Cu, Zr, Nb, Mo, Tc, Ru, Rh, Rd, Ag, Hf, Ta, W, Re, Os, Ir, Pt, Au, Hg, and an oxide thereof.
